(19) United States
(12) Patent Application Publication
(10) Pub. No.: US 2021/0367575 A1
(43) Pub. Date: Nov. 25, 2021

(54) FILTER CIRCUIT AND ELECTRONIC EQUIPMENT

(71) Applicant: TCL CHINA STAR OPTOELECTRONICS TECHNOLOGY CO., LTD, Shenzhen (CN)

(72) Inventor: Jianfeng XIAO, Shenzhen (CN)

(73) Assignee: TCL CHINA STAR OPTOELECTRONICS TECHNOLOGY CO., LTD, Shenzhen (CN)

(21) Appl. No.: 16/627,368

(22) PCT Filed: Dec. 26, 2019
(86) PCT No.: PCT/CN2019/128700

§ 371 Date: Dec. 30, 2019

(30) Foreign Application Priority Data
Dec. 19, 2019 (CN) 201911318133.2

(51) Int. Cl. H03H 7/01

(52) U.S. Cl. CPC H03H 7/0115

(57) ABSTRACT

A filter circuit and an electronic equipment are provided. The filter circuit, electrically connected between a power module and an integrated circuit control module, includes a capacitor unit, a ferrite bead component, and a filter capacitor. The capacitor unit is electrically connected to a first node of the power module. The ferrite bead component is electrically connected to a second node of the integrated circuit control module and the first node of the power module. The filter capacitor is electrically connected to the second node of the integrated circuit control module. The ferrite bead component has a zero resistance. This reduces the ripple of the power signal, outputted by the power module, after the power signal passes through the ferrite bead component, solving the above-mentioned EMI issue, and improving the performance of the IC.

### FIELD OF THE INVENTION

The present invention relates to a display technique, and more particularly, to a filter circuit and an electronic equipment.

### BACKGROUND

The ripple is an unavoidable phenomenon that happens to a DC power due to its voltage variances. A conventional driving circuit utilizes a filter circuit to suppress the ripple.

FIG. 5a and FIG. 5b respectively depict the waveforms at the output end of power module and the power input pin of the integrated circuit (IC), which reflect the waveforms before and after filter operations. The conventional filter circuit is often installed between the output end of the power module and the input pin of the IC. However, the conventional filter circuit often comprises a capacitor and an inductor, which are charged and discharged to form a resonance such that the ripple increases at the output end of the filter circuit. Further, the peaks of the ripple become a noise, which introduces electromagnetic interference (EMI) and thus ruin the performance of the IC.

### SUMMARY

One objective of an embodiment of the present invention is to provide a filter circuit, to solve the above-mentioned EMI issue, which may ruin the performance of the IC.

According to an embodiment of the present invention, a filter circuit, electrically connected between a power module and an integrated circuit control module is disclosed. The filter circuit comprises: a capacitor unit, electrically connected to a first node of the power module; a ferrite bead component, electrically connected to a second node of the integrated circuit control module and the first node of the power module; and a filter capacitor, electrically connected to the second node of the integrated circuit control module; wherein the ferrite bead component has a zero resistance.

Optionally, the capacitor unit comprises a first capacitor and a second capacitor connected in parallel and the first capacitor and the second capacitor have different capacitances.

Optionally, the first capacitor is a tantalum capacitor.

Optionally, the second capacitor is a ceramic capacitor.

Optionally, the ferrite bead component is made with an iron-magnesium alloy, an iron-nickel alloy, or a ferrite.

According to an embodiment of the present invention, an electronic equipment is disclosed. The electronic equipment comprises: a power module, having a first node for outputting a power signal; an integrated circuit control module, having a second node for outputting a filtered power signal; a capacitor unit, electrically connected to the first node; a ferrite bead component, electrically connected between the second node and the first node; and a filter capacitor, electrically connected to the second node; wherein the ferrite bead component has a zero resistance.

According to an embodiment of the present invention, an electronic equipment is disclosed. The electronic equipment comprises: a power module, having a first node for outputting a power signal; an integrated circuit control module, having a second node for outputting a filtered power signal; a capacitor unit, electrically connected to the first node; and a ferrite bead component, electrically connected between the second node and the first node; wherein no capacitor is installed between the ferrite bead component and the integrated circuit control module.

Optionally, the first capacitor is a tantalum capacitor.

Optionally, the second capacitor is a ceramic capacitor.

Optionally, the ferrite bead component is made with an iron-magnesium alloy, an iron-nickel alloy, or a ferrite.

In contrast to the conventional art, an embodiment of the present invention provides a filter circuit. The filter circuit sets the resistance of the ferrite bead component as 0 ohm. This reduces the ripple of the power signal, outputted by the power module, after the power signal passes through the ferrite bead component. Furthermore, an embodiment of the present invention also provides an electronic equipment. The electronic equipment does not install a capacitor between the ferrite bead component and the IC control module. This avoids the series-connected resonance phenomenon, solves the above-mentioned EMI issue, and improves the performance of the IC.

These and other features, aspects and advantages of the present disclosure will become understood with reference to the following description, appended claims and accompanying figures.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a diagram of a structure of an electronic equipment according to an embodiment of the present invention.

FIG. 2 is a diagram of a structure of an electronic equipment according to another embodiment of the present invention.

FIG. 3 is a diagram of a structure of a ferrite bead component.

FIG. 4 is a diagram of a structure of an electronic equipment according to another embodiment of the present invention.

FIG. 5a and FIG. 5b respectively depicts the waveforms at the output end of power module and the power input pin of the integrated circuit (IC), which reflects the waveforms before and after filter operations.

### DETAILED DESCRIPTION OF PREFERRED EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

In addition, the term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features. In the description of the present disclosure, the meaning of “plural” is two or more, unless otherwise specifically defined.

Moreover, despite one or more implementations relative to the present disclosure being illustrated and described, equivalent alterations and modifications will occur to others skilled in the art upon reading and understanding this specification and the annexed drawings. The present disclosure comprises such modifications and variations, and is to be limited only by the terms of the appended claims. In particular, regarding the various functions performed by the above described components, the terms used to describe such components (i.e. elements, resources, etc.) are intended to correspond (unless otherwise indicated) to any component, which performs the specified function of the described component (i.e., that is, functionally equivalent), even though not structurally equivalent to the disclosed structure which performs the function in the illustrated implementations of the disclosure. In addition, although a particular feature of the disclosure may have been disclosed with respect to only one of several implementations, such a feature may be combined with one or more other features of the other implementations as may be desired and advantageous for any given or particular application. Also, to the extent that the terms “including”, “includes”, “having”, “has”, “with”, or variants thereof are used in the detailed description or in the claims, such terms are intended to be inclusive in a manner similar to the term “comprising”.

Embodiments of the present application are illustrated in detail in the accompanying drawings, in which like or similar reference numerals refer to like or similar elements or elements having the same or similar functions throughout the specification. The embodiments described below with reference to the accompanying drawings are exemplary and are intended to be illustrative of the present application, and are not to be construed as limiting the scope of the present application.

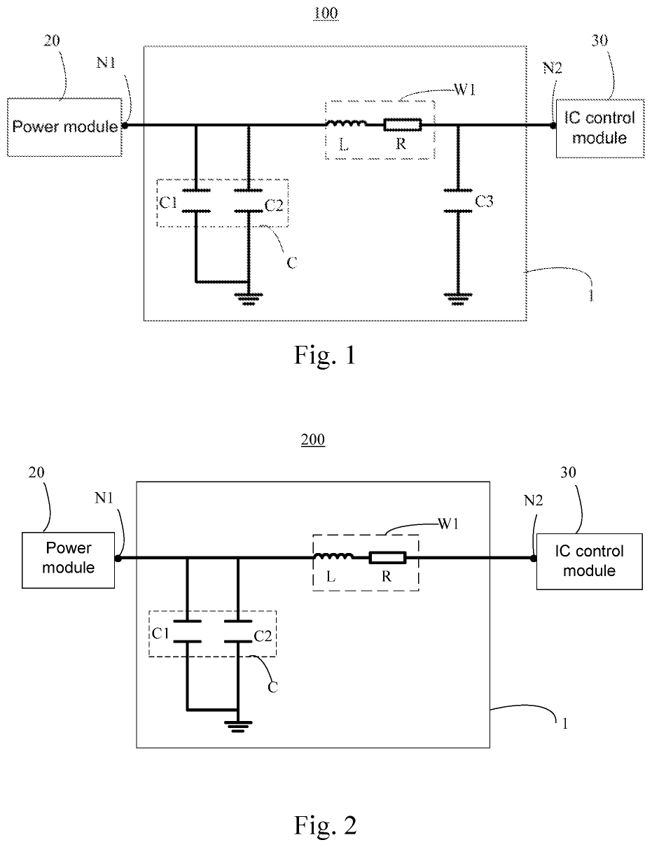

Please refer to FIG. 1. FIG. 1 is a diagram of a structure of an electronic equipment 100 according to an embodiment of the present invention. The electronic equipment 100 comprises a power module 20, an integrated circuit (IC) control module 30 and a filter circuit 1. The filter circuit 1 is electrically connected between the first node N1 of the power module 20 and the second node N2 of the IC control module 30. The first node N1 of the power module 20 is used to output a power signal. The second node N2 of the IC control module 30 is used to input the power signal. The power module 20 is used to provide a current to the IC control module 30. In order to filter the AC component of the current, the filter circuit 1 is installed between the power module 20 and the IC control module 30. The filter circuit 1 is used to reduce the ripple or EMI of the power signal.

The filter circuit 1 comprises a capacitor unit C, a filter capacitor C3, and a ferrite bead component W1. The ferrite bead component W1 could be a ferrite bead filter, which is equivalent to a resistor R and an inductor L.

The ferrite bead component W1 could be a ferrite bead filter, which could be made with an iron-magnesium alloy, an iron-nickel alloy, or a ferrite. The ferrite bead component W1 has a high resistivity and a high magnetic permeability and thus is equivalent to series-connected a resistor R and an inductor L. However, its resistivity and the magnetic permeability vary according to frequencies and it has a better high-frequency filter characteristic than the inductor because it has a high-frequency impedance. Therefore, the ferrite bead component W1 could have a higher impedance in a wider frequency range and raises the frequency tuning filter effect. In this embodiment, the ferrite bead component W1 is used to suppress the radio frequency (RF) noises in the transmission line between the power module 20 and the IC control module 30. Here, the energy of the RF noise is superposed on the AC component of the DC power. The ferrite bead component W1 is used to suppress these unwanted energies. Preferably, the chip bead could be used as the ferrite bead component to suppress the RF noises. In this embodiment, the resistance of the ferrite bead component W1 is set as 0. This reduces the ripple of the power signal inputted into the IC control module 30 after the power single passes through the ferrite bead component W1 from the power module 20.

In order to allow the capacitor C to filter different AC signals, the capacitor C could comprises two, but not limited to two, series-connected the first capacitor C1 and the second capacitor C2. The first capacitor C1 and the second capacitor C2 have different capacitances. For example, the first capacitor C1 could be a tantalum capacitor having a capacitance larger than or equal to 20 μF for filtering out AC signal having a frequency less than or equal to 200 kHz. In addition, the second capacitor C2 could be a ceramic capacitor having a capacitance less than or equal to 0.1 μF for filtering out AC signal having a frequency larger than or equal to 1 MHz. The higher the capacitance is, the lower the impedance is and thus the corresponding filtering performance is better. For the noise having a frequency larger than or equal to 1 MHz, the ceramic capacitor having a low capacitance is used to filter the noise to make sure the working frequency of the capacitor C is much lower than its resonance frequency.

FIG. 2 is a diagram of a structure of an electronic equipment 200 according to another embodiment of the present invention. The electronic equipment 200 comprises a power module 20, an IC control module 30 and a filter 1. The filter circuit 1 is electrically connected between the first node N1 of the power module 20 and the second node N2 of the IC control module 30. The first node N1 of the power module 20 is used to output a power signal. The second node N2 of the IC control module 30 is used to input the power signal. The power module 20 is used to provide a current to the IC control module 30. In order to filter the AC component of the current, the filter circuit 1 is installed between the power module 20 and the IC control module 30. The filter circuit 1 is used to reduce the ripple or EMI of the power signal.

The filter circuit 1 comprises a capacitor unit C and a ferrite bead component W1. The ferrite bead component W1 could be a ferrite bead filter, which is equivalent to a resistor R and an inductor L. The ferrite bead component W1 could be a ferrite bead filter, which could be made with an iron-magnesium alloy, an iron-nickel alloy, or a ferrite. The ferrite bead component W1 has a high resistivity and a high magnetic permeability and thus is equivalent to series-connected a resistor R and an inductor L. However, its resistivity and the magnetic permeability vary according to frequencies and it has a better high-frequency filter characteristic than the inductor because it has a high-frequency impedance. Therefore, the ferrite bead component W1 could have a higher impedance in a wider frequency range and raises the frequency tuning filter effect. In this embodiment, the ferrite bead component W1 is used to suppress the radio frequency (RF) noises in the transmission line between the power module 20 and the IC control module 30. Here, the energy of the RF noise is superposed on the AC component of the DC power. The ferrite bead component W1 is used to suppress these unwanted energies. Preferably, the chip bead could be used as the ferrite bead component to suppress the RF noises. In this embodiment, no capacitor is installed between the ferrite bead component W1 and the IC control module 30. In this way, the power signal outputted from the ferrite bead component W1 does not pass through the capacitor, which is connected to the ground. Therefore, in the low-frequency band, there is no LC resonance. Thus, the electronic equipment 200 of this embodiment does not enlarge the ripple of the power signal inputted into the IC control module 30 and does not influence the performance of the IC control module 30.

In some embodiments, please refer to FIG. 3. FIG. 3 is a diagram of a structure of a ferrite bead component. The resistance R comprises sub-resistors R1 connected in parallel. The resistance of the sub-resistor R1 ranges from 0 to 10 ohms. Specifically, since the ferrite bead needs to have a high resistivity, multiple parallel sub-resistors R1 are installed to make the ferrite bead have a high resistivity to raise the high-frequency noise suppression effect.

In addition, the inductor L of the ferrite bead component W1 could be made with an enamel coated wire and the inductance of the inductor L could be 0.1-2200 mH.

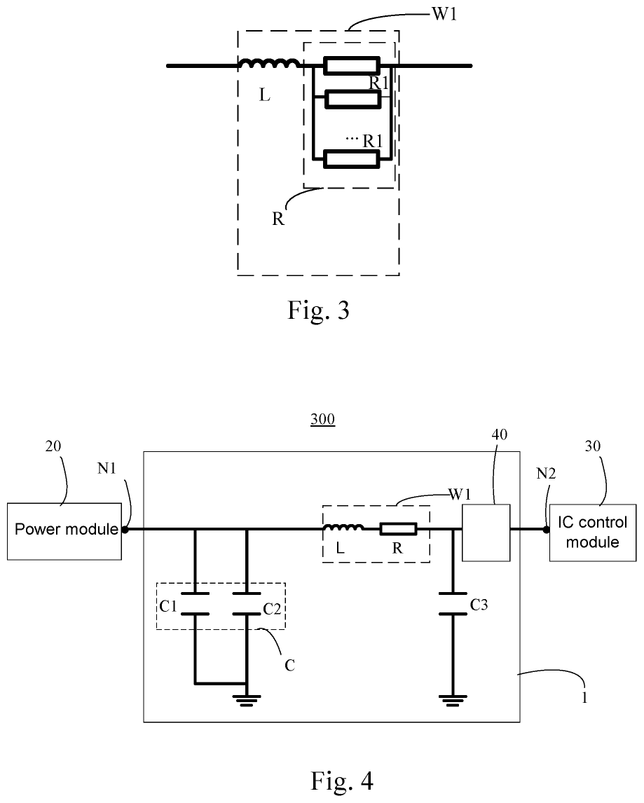

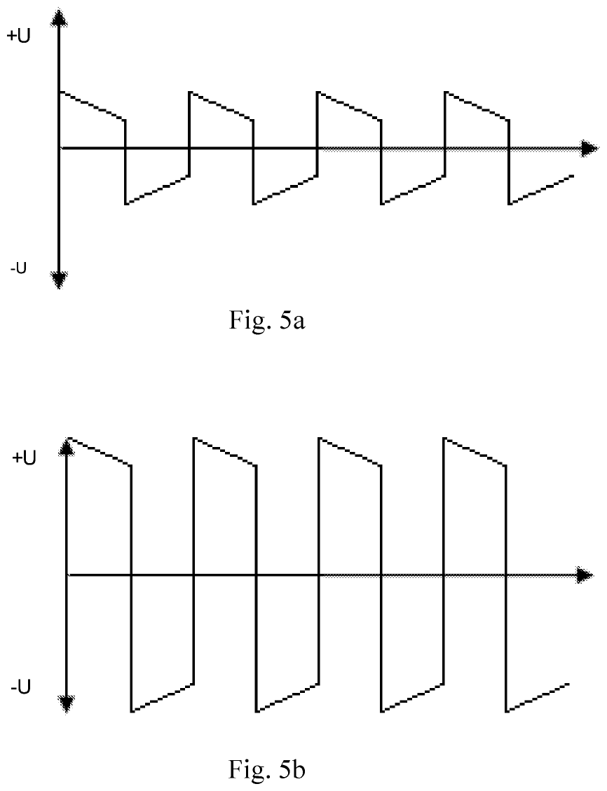

FIG. 4 is a diagram of a structure of an electronic equipment 300 according to another embodiment of the present invention. In an embodiment, the filter circuit 1 further comprises a current-limiting component 40, which is installed between the ferrite bead component W1 and the IC control module 30 to limit the voltage level of the second node N2 such that the voltage level of the second node N2 is not less than 4V. Specifically, the current-limiting component 40 could be a current-limiting resistor to reduce the current of the first node N1 of the filter circuit. For example, a current-limiting resistor could be added at one end of the ferrite bead component W1 to reduce the current passing through the ferrite bead component W1. This could avoid damaging the ferrite bead component W1.

The above-mentioned electronic equipments 100, 200 and 300 could be a cell phone, a tablet, a TV, a display, a laptop, a digital frame, a navigator, or any other devices having filter function.

Consequently, an embodiment of the present invention provides a filter circuit. The filter circuit sets the resistance of the ferrite bead component as 0 ohm. This reduces the ripple of the power signal, outputted by the power module, after the power signal passes through the ferrite bead component. Furthermore, an embodiment of the present invention also provides an electronic equipment. The electronic equipment does not install a capacitor between the ferrite bead component and the IC control module. This avoids the series-connected resonance phenomenon, solves the above-mentioned EMI issue, and improves the performance of the IC.

Above are embodiments of the present invention, which does not limit the scope of the present invention. Any modifications, equivalent replacements or improvements within the spirit and principles of the embodiment described above should be covered by the protected scope of the invention.

What is claimed is:

1. A filter circuit, electrically connected between a power module and an integrated circuit control module, the filter circuit comprising:
a capacitor unit, electrically connected to a first node of the power module;
a ferrite bead component, electrically connected to a second node of the integrated circuit control module and the first node of the power module; and
a filter capacitor, electrically connected to the second node of the integrated circuit control module;
wherein the ferrite bead component has a zero resistance.

2. The filter circuit of claim 1, wherein the capacitor unit comprises a first capacitor and a second capacitor connected in parallel and the first capacitor and the second capacitor have different capacitances.

3. The filter circuit of claim 1, wherein the first capacitor is a tantalum capacitor.

4. The filter circuit of claim 1, wherein the second capacitor is a ceramic capacitor.

5. The filter circuit of claim 1, wherein the ferrite bead component is made with an iron-magnesium alloy, an iron-nickel alloy, or a ferrite.

6. An electronic equipment, comprising:
a power module, having a first node for outputting a power signal;
an integrated circuit control module, having a second node for outputting a filtered power signal;
a capacitor unit, electrically connected to the first node;
a ferrite bead component, electrically connected between the second node and the first node; and
a filter capacitor, electrically connected to the second node;
wherein the ferrite bead component has a zero resistance.

7. An electronic equipment, comprising:
a power module, having a first node for outputting a power signal;
an integrated circuit control module, having a second node for outputting a filtered power signal;
a capacitor unit, electrically connected to the first node; and
a ferrite bead component, electrically connected between the second node and the first node;
wherein no capacitor is installed between the ferrite bead component and the integrated circuit control module.

8. The electronic equipment of claim 7, wherein the first capacitor is a tantalum capacitor.

9. The electronic equipment of claim 8, wherein the second capacitor is a ceramic capacitor.

10. The electronic equipment of claim 7, wherein the ferrite bead component is made with an iron-magnesium alloy, an iron-nickel alloy, or a ferrite.
